(19) United States
(12) Patent Application Publication
(10) Pub. No.: US 2011/0310571 A1
(43) Pub. Date: Dec. 22, 2011

(54) Electronic Apparatus

(76) Inventor: Ichioh Murakami, Akishima-shi (JP)

(21) Appl. No.: 13/045,368

(22) Filed: Mar. 10, 2011

(30) Foreign Application Priority Data
Jun. 18, 2010 (JP) 2010-139492

(51) Int. Cl. H05K 5/00

(52) U.S. Cl. 361/752

(57) ABSTRACT

According to one embodiment, an electronic apparatus includes: a housing formed with an opening; a battery module including a connection portion and at least partly accommodated in the opening; a circuit board accommodated in the housing; a connector portion including: a terminal portion including a terminal connected to the connection portion of the battery portion; and a side portion connected to the terminal portion and including a depressed portion depressed toward the terminal portion; and a fitted member fitted in the depressed portion and configured to fix the connector portion and the circuit board.

### CROSS REFERENCE TO RELATED APPLICATION(S)

The application is based upon and claims the benefit of priority from Japanese Patent Application No. 2010-139492 filed on Jun. 18, 2010, the entire contents of which are incorporated herein by reference.

### BACKGROUND

1. Field

An embodiment of the present invention relates to an electronic apparatus.

2. Description of the Related Art

Conventionally, electronic apparatuses having a battery pack have been known.

In recent years, it has been required of electronic apparatuses that parts be mounted in the housing with higher density.

### BRIEF DESCRIPTION OF THE DRAWINGS

A general configuration that implements the various features of embodiments will be described with reference to the drawings. The drawings and the associated descriptions are provided to illustrate embodiments and not to limit the scope of the embodiments.

FIG. 1 is a perspective view of a portable computer as an electronic apparatus according to an embodiment when viewed from above;

FIG. 2 is a perspective view of the portable computer of FIG. 1 when viewed from below;

FIG. 3 is an exploded perspective view of the portable computer of FIG. 1 when viewed from below with a battery module being detached;

FIG. 4 is a perspective view of the portable computer of FIG. 1 when viewed from below with the battery module being detached;

FIG. 5 is a bottom view of the portable computer of FIG. 1;

FIG. 6 is a cross-sectional view taken along the line VI-VI in FIG. 5;

FIG. 7 is a cross-sectional view showing the portable computer of FIG. 1 with the battery module being detached in FIG. 6;

FIG. 8 is a cross-sectional view taken along the line VIII-VIII in FIG. 5;

FIG. 9 is a cross-sectional view showing the portable computer of FIG. 1 with the battery module being detached in FIG. 8;

FIG. 10 is a cross-sectional view taken along the line X-X in FIG. 5;

FIG. 11 is a cross-sectional view showing the portable computer of FIG. 1 with the battery module being detached in FIG. 10;

FIG. 12 is an exploded perspective view of the portable computer of FIG. 1 when viewed from above with the battery module being detached;

FIG. 13 is a transverse cross-sectional view showing the battery module of the portable computer of FIG. 1;

FIG. 14 is a perspective view showing a battery connector according to the present embodiment; and

FIG. 15 is a cross-sectional view of the battery connector according to the present embodiment.

### DETAILED DESCRIPTION

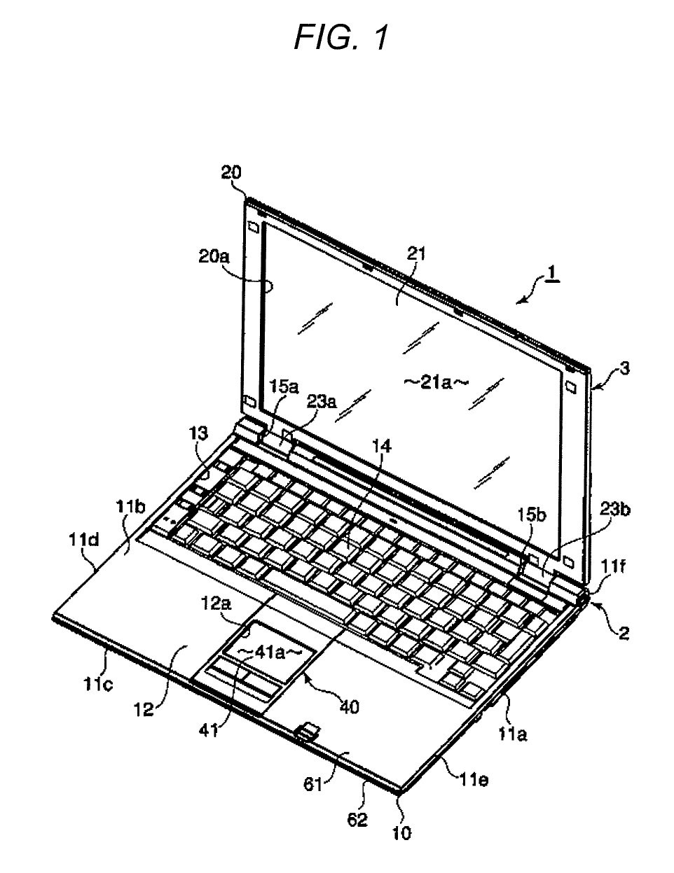

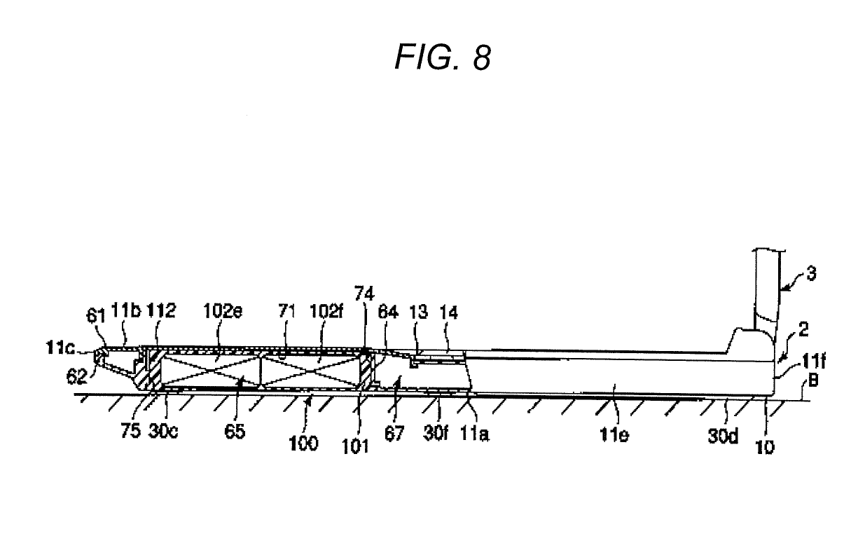

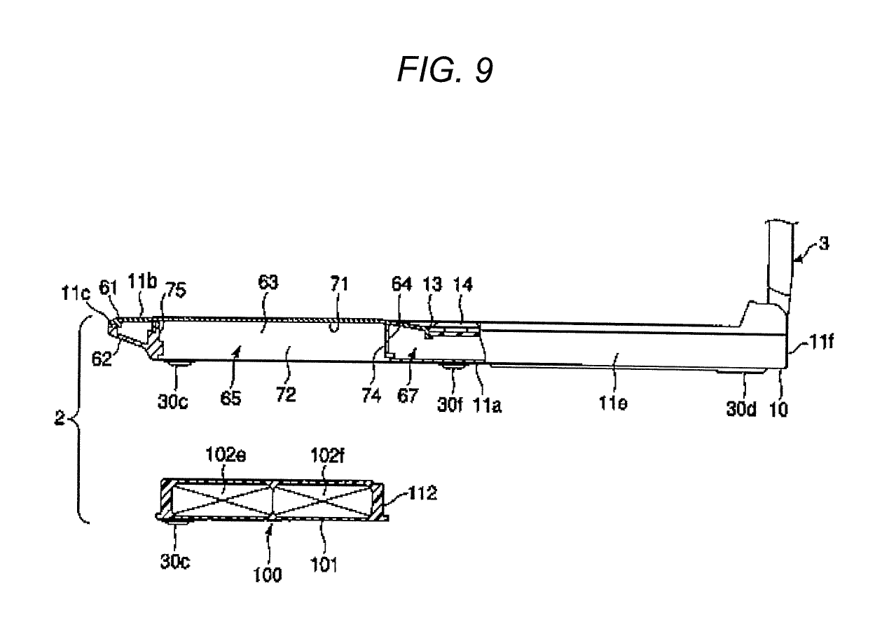

An embodiment of the present invention will be described with reference to FIGS. 1 to 13. In the present embodiment, an electronic apparatus of the present invention is shown with an example in which the present invention is applied to a portable computer. FIGS. 1 to 3 show a portable computer 1 as the electronic apparatus. The portable computer 1 has a main module 2 and a display module 3.

As shown in FIG. 1, the main module 2 has a first housing 10 having a flat box shape. The first housing 10 has a bottom wall 11a, an upper wall 11b, a front wall 11c, left and right side walls 11d and 11e, and a rear wall 11f. The outer surface of the upper wall 11b has a palm rest 12 on the hand side (front side).

The upper wall 11b of the first housing 10 has a keyboard attachment portion 13 in the rear of the palm rest 12. To the keyboard attachment portion 13, a keyboard 14 used for inputting numbers, characters and the like is attached.

The first housing 10 has a pair of coupling concave portions 15a and 15b at the rear end thereof. The coupling concave portions 15a and 15b are formed as depressions opened toward the front, bottom and rear of the first housing 10. The coupling concave portions 15a and 15b are provided so as to be separated from each other in the direction of the width of the main module 2 (right-left direction).

The display module 3 has a second housing 20 and a liquid crystal display panel 21 as the display panel. The liquid crystal display panel 21 is accommodated in the second housing 20. The liquid crystal display panel 21 has a screen 21a displaying an image. The second housing 20 has an opening 20a for exposing the screen 21a. The screen 21a is exposed out of the second housing 20 through the opening 20a.

The second housing 20 has a pair of coupling leg portions 23a and 23b at one end thereof. The coupling leg portions 23a and 23b are disposed so as to be separated from each other in the direction of the width of the second housing 20, and are directed into the coupling concave portions 15a and 15b of the first housing 10, respectively. The coupling leg portions 23a and 23b are rotatably supported by the coupling concave portions 15a and 15b through metal hinges (not shown), respectively.

Consequently, the display module 3 is pivotable between a closed position where it lies over the main module 2 so as to cover the palm rest 12, the keyboard 14 and the like from above and an opened position where it uprises with respect to the main module 2 so as to expose the palm rest 12, the keyboard 14, the screen 21a and the like.

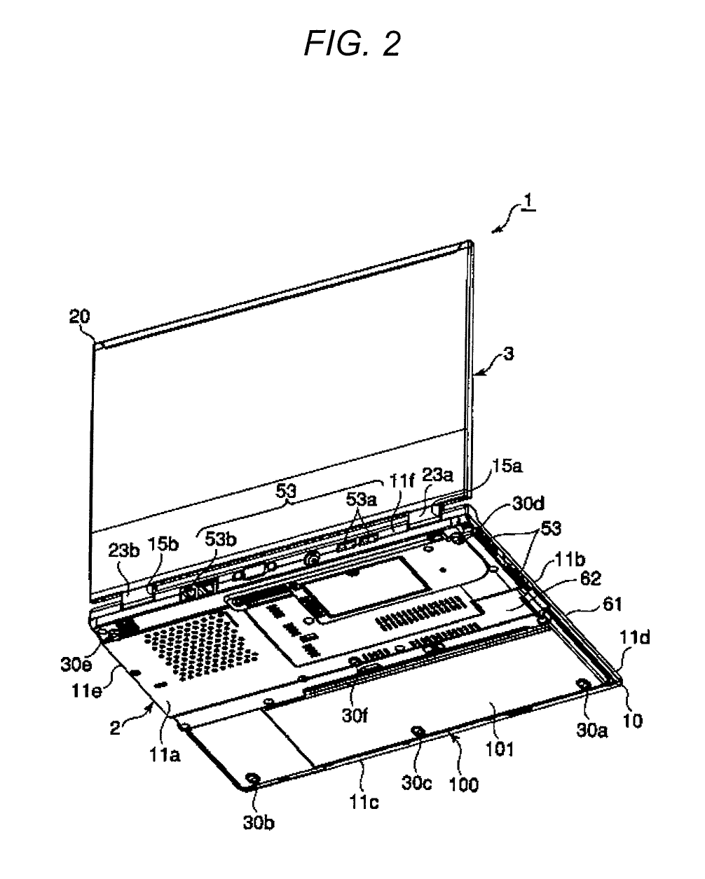

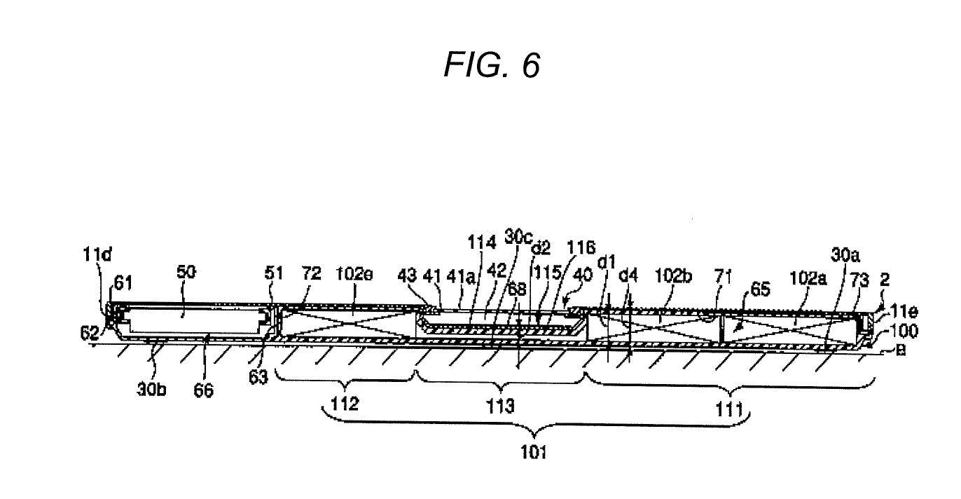

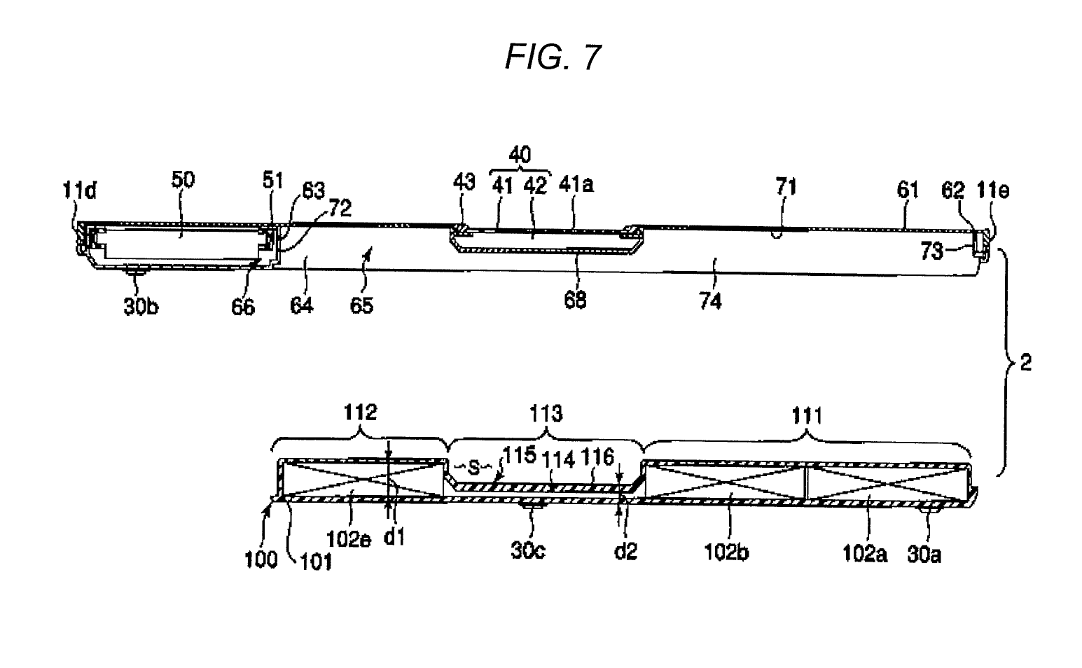

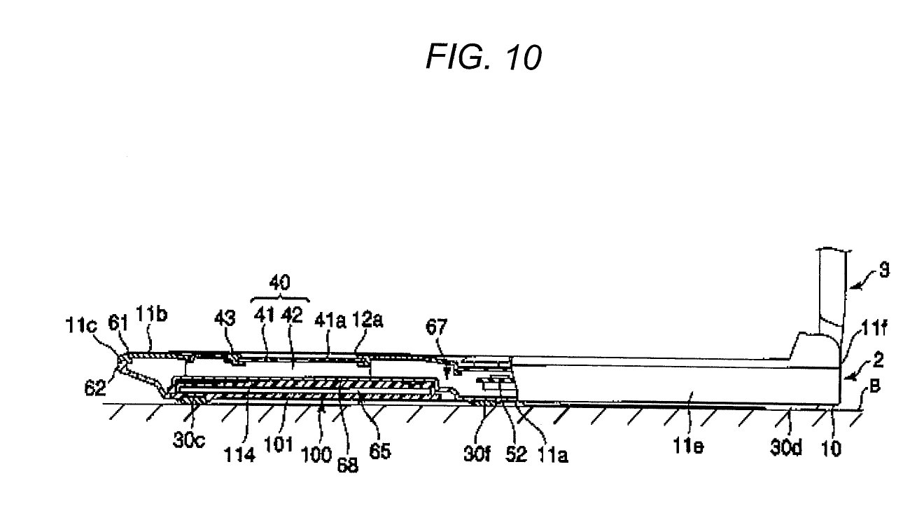

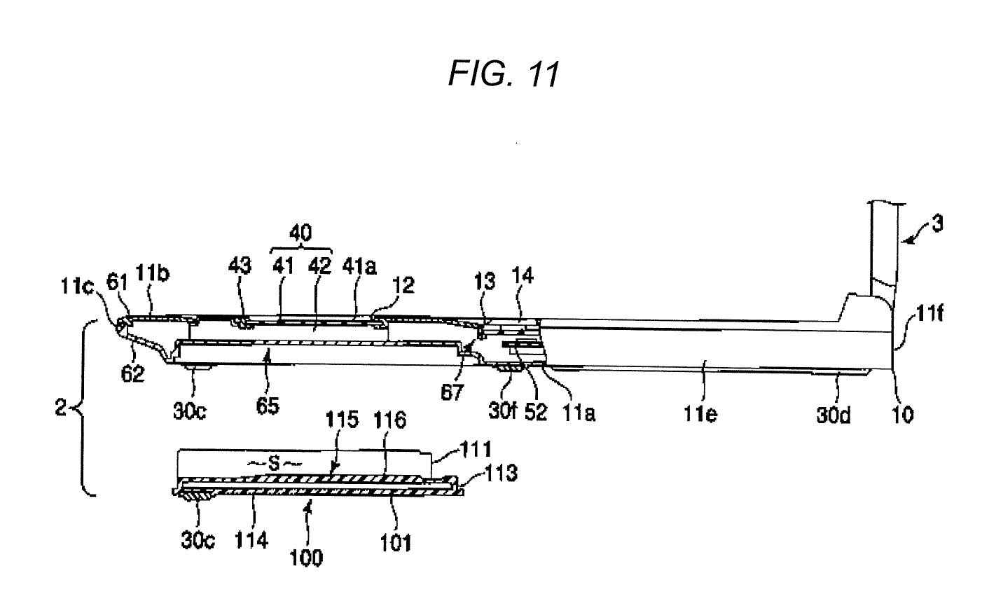

In the first housing 10, a pointing device (see FIGS. 1, 6, 7, 10 and 11) 40 as an electronic part, a hard disk drive (hereinafter, referred to as HDD, see FIGS. 6 and 7) 50 and a printed wiring board (circuit board, see FIGS. 10 and 11) 52 are accommodated. The first housing 10 has a battery module (a battery pack, a battery module, see FIGS. 2, 3, 6 and 7) 100.

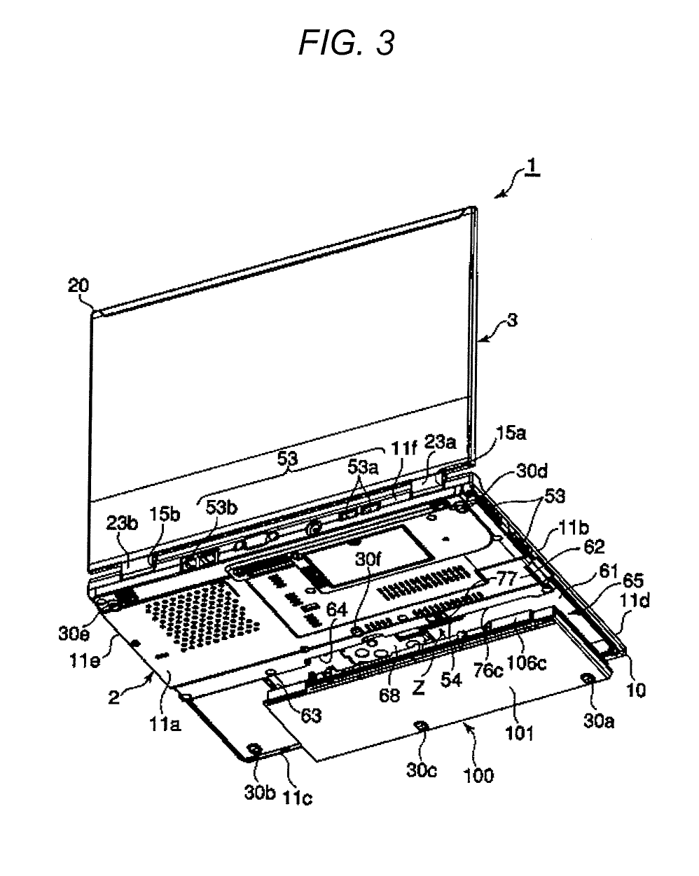

More specifically, as shown in FIGS. 3, 4, 6, 8, 10, etc., the first housing 10 has a first member 61 and a second member 62. The first and second members 61 and 62 are made of a metal material such as magnesium alloy. The first member 61 constitutes the upper wall 11b, the front wall 11c, the left and right side walls 11d and 11e, and the rear wall 11f of the first housing 10. The second member 62 constitutes part of the bottom wall 11a of the first housing 10.

The second member 62 has a first partition wall 63 and a second partition wall 64 that rise upward. These divide the inside of the first housing 10 into a first accommodating portion 65 as an opening, a second accommodating portion 66 and a third accommodating portion 67. The first partition wall 63 is provided between the first accommodating portion 65 and the second accommodating portion 66. The second partition wall 64 is provided between the first accommodating portion 65 and the third accommodating portion 67.

The second member 62 has, in the first accommodating portion 65, a pointing device support portion 68 as a mechanism part that horizontally extends from the rising end of the second partition wall 64. The pointing device support portion 68 swells downward (see FIG. 10). The pointing device support portion 68 may be formed of the first member 61.

The first accommodating portion 65 extends in the direction of the width of the first housing 10 under the palm rest 12. The first accommodating portion 65 is formed of a concave portion opened toward the bottom of the first housing 10. The second accommodating portion 66 is disposed in a position on the side of the side wall lie so as to be aligned with the first accommodating portion 65 in the direction of the width. The third accommodating portion 67 is disposed under the keyboard 14, that is, in the rear of the first and second accommodating portions 65 and 66.

As shown in FIG. 1, the first housing 10 has the pointing device 40 such as a touch pad in the center of the palm rest 12. As shown in FIGS. 6, 7, 10 and 11, the pointing device 40 has an input module 41 and a driving device 42. One surface (upper surface) of the input module 41 is a flat input surface 41a. The input module 41 is supported by a frame-form support member 43. The driving device 42 is accommodated in the first accommodating portion 65 that is inside the first housing 10, in a state of being supported by the pointing device support portion 68.

On the upper wall 11b of the first housing 10, an opening 12a for exposing the input surface 41a is provided in the center of the palm rest 12. As shown in FIG. 1, the input surface 41a of the pointing device 40 is exposed out of the first housing 10 through the opening 12a.

Examples of the input module 41 of the pointing device 40 include a sheet that detects capacitance and a pressure sensitive film that detects pressure, and any of these may be used. The pointing device 40 may be one to which information is inputted through the upper wall 11b. In that case, the opening 12a may be omitted.

In the portable computer 1, it is necessary that the pointing device 40 be situated in the center of the palm rest 12. If the pointing device 40 is situated in a position shifted from the center of the palm rest 12, the pointing device 40 not only is awkward to use but also is an obstruction to the operation of the keyboard 14. Therefore, this is not very desirable.

As shown in FIGS. 6 and 7, the HDD 50 is disposed on the side of the side wall 11e below the palm rest 12. The HDD 50 is accommodated in the second accommodating portion 66 that is inside the first housing 10, in a state of being supported by an HDD support member 51. The HDD support member 51 is screwed to the first housing 10.

As shown in FIGS. 10 and 11, the printed wiring board 52 is disposed below the keyboard 14. That is, the printed wiring board 52 is accommodated in the third accommodating portion 67. The printed wiring board 52 is screwed to the first housing 10. When the first housing 10 has a PC card slot for inserting a PC card, it may be performed to dispose the PC card slot in the second accommodating portion 66 and dispose the HDD 50 in the third accommodating portion 67.

Although not shown, a connector panel is mounted in the third accommodating portion 67 that is inside the first housing 10. The connector panel has connectors 53 such as a USB connector 53a and a LAN connector 53b. As shown in FIGS. 2 and 3, these connectors 53 are exposed to the outside through the rear wall 11f and the side wall 11d. These connectors 53 are electrically connected to the printed wiring board 52.

As shown in FIGS. 2 and 3, the battery module 100 is disposed so as to be aligned with the HDD 50 in the direction of the width under the palm rest 12. The battery module 100 is fitted in the first accommodating portion 65 to constitute part of the bottom wall 11a of the first housing 10.

As described above, the pointing device 40 is disposed substantially in the center of the palm rest 12. Therefore, the battery module 100 partly coincides with the pointing device 40 (the pointing device support portion 68) in the direction of the thickness (vertical direction). For this reason, the battery module 100 of the portable computer 1 of the present embodiment has a recessed portion 115 so that its outside shape is substantially the same as that of the first accommodating portion 65.

Specifically, the first accommodating portion 65 is defined by a bottom surface 71, a pair of upright end surfaces 72 and 73 uprising from the bottom surface 71, and a pair of upright side surfaces 74 and 75. The bottom surface 71 is defined by the inner surface of the palm rest 12 and the lower surface of the pointing device support portion 68. That is, the bottom surface 71 is defined by the inner surface of the first member 61 and the outer surface of the second member 62, and the part where the pointing device support portion 68 is provided projects downward with respect to the inner surface of the first member 61.

Of the pair of upright end surfaces 72 and 73, the upright end surface 72 is the first accommodating portion 65 side end surface of a pair of end surfaces of the first partition wall 63, and the other upright end surface 73 is the inner surface of the side wall 11d. Of the pair of upright side surfaces 74 and 75, the upright side surface 74 is the first accommodating portion 65 side end surface of a pair of end surfaces of the second partition wall 64, and the other upright side surface 75 is the inner surface of the front wall 11c.

As shown in FIGS. 6, 7, 12, 13, etc., the battery module 100 is provided with a case 101 made of an insulating material such as synthetic resin, a plurality of battery cells (storage modules) 102a to 102f, and a circuit board 103. As the battery cells 102a to 102f, so-called angular cells the outside shape of which is a flat box shape may be used. As the battery cells 102a to 102f, so-called circular cells the outside shape of which is cylindrical may be used. The battery cells 102a to 102f are each a secondary cell.

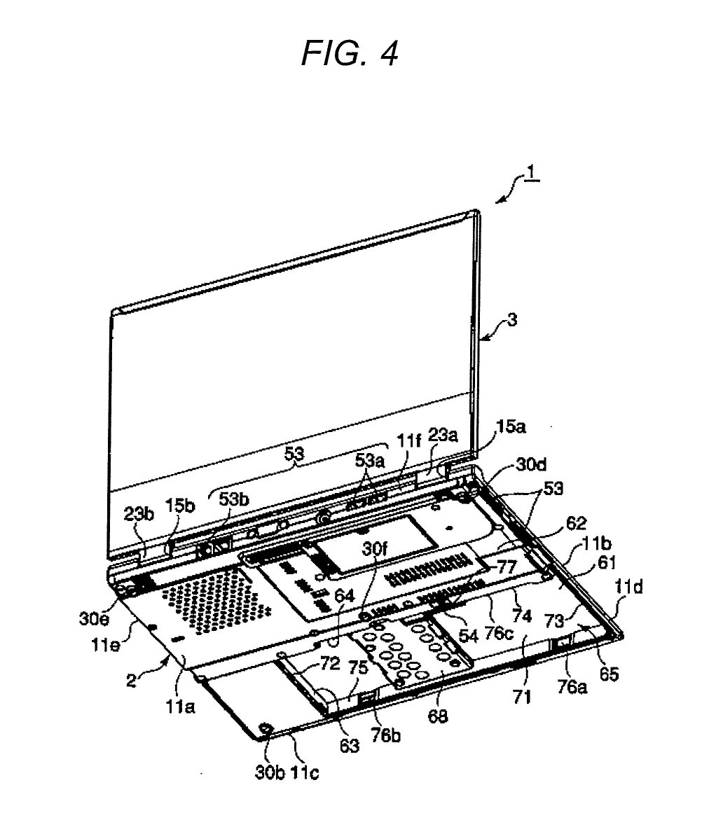

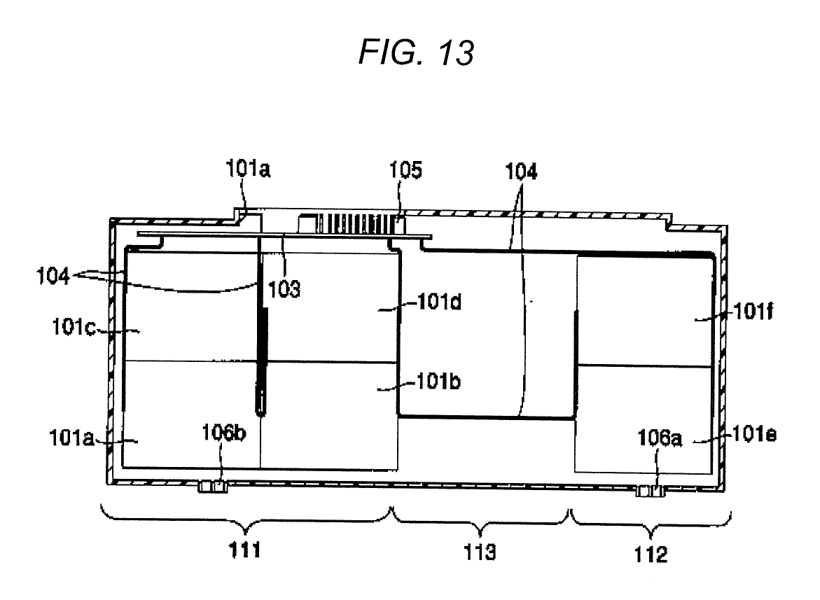

As shown in FIGS. 4, 13, etc., the case 101 has: a first part 111 accommodating one or more, for example, four battery cells 102 to 102d; a second part 112 accommodating one or more, for example, two battery cells 102e and 102f; and a third part 113 connecting the first part 111 and the second part 112 together. That is, in this battery module 100, the parts accommodating the battery cells 102a to 102f are divided with electrical connection therebetween being maintained.

The plus sides and the minus sides of the four battery cells 102a to 102d accommodated in the first accommodating portion 65 are each electrically connected to the circuit board 103 through wirings (for example, thin plates) 104. Likewise, the plus sides and the minus sides of the two battery cells 102e and 102f accommodated in the second accommodating portion 66 are each electrically connected to the circuit board 103 through the wirings (for example, thin plates) 104. Thus, this battery module 100 has a so-called three in series, two in parallel configuration.

The battery cells 102a to 102f themselves have an electrically resistive component. For this reason, the overall electrical balance of the battery module 100 can be adjusted, for example, by changing the thickness (resistance) of the wirings 104 electrically connecting the battery cells 102a to 102f together.

The third part 113 has the recessed portion 115 provided so as to avoid the pointing device 40 as an electronic part (the pointing device support portion 68 as a mechanical part). In the battery module 100 of the portable computer 1 of the present embodiment, the recessed portion 115 is thinner than the first and second parts 111 and 112. In other words, the recessed portion 115 has a thin part 114 that is thinner than the first and second parts 111 and 112. As shown in FIG. 7, the thickness d2 of the thin part 114 is smaller than the thickness d1 of the battery cells 102a to 102f. Moreover, the thickness d2 of the thin part 114 is smaller than the thickness d4 of the first and second parts 111 and 112.

The recessed portion 115 (thin part 114) can be realized, for example, by providing a concave portion (groove) 116 on, of a pair of upper and lower end surfaces of the case 101, the end surface (upper surface) facing the pointing device support portion 68. In this battery module 100, the case 101 is formed so that the thickness of the bottom 116a of the concave portion 116 (that is, the thickness of the thin part 114) d2 is thinner than the thickness d1 of the battery cells 102a to 102f. The other end surface of the case 101 (the surface opposite to the surface facing the pointing device support portion 68, the lower surface) is a flat rectangular surface.

As shown in FIG. 13, the circuit board 103 is provided with a connector (connection portion) 105 connectable to a power connector (battery connector) 54. The circuit board 103 is accommodated in the case 101 so as to be parallel to the direction of the thickness of the battery module 100 (so as to be orthogonal to the flat end surface [lower surface] of the case 101). The circuit board 103 and the connector 105 are provided, for example, in the first part 111.

Of a pair of side surfaces of the case 101, one side surface (rear surface) has an opening 101a, and the connector 105 is exposed to the outside through this opening 101a. The circuit board 103 and the connector 105 may be provided in the second part 112 or the third part 113. The circuit board 103 and the connector 105 may be provided in different ones of the first to third parts 111 to 113.

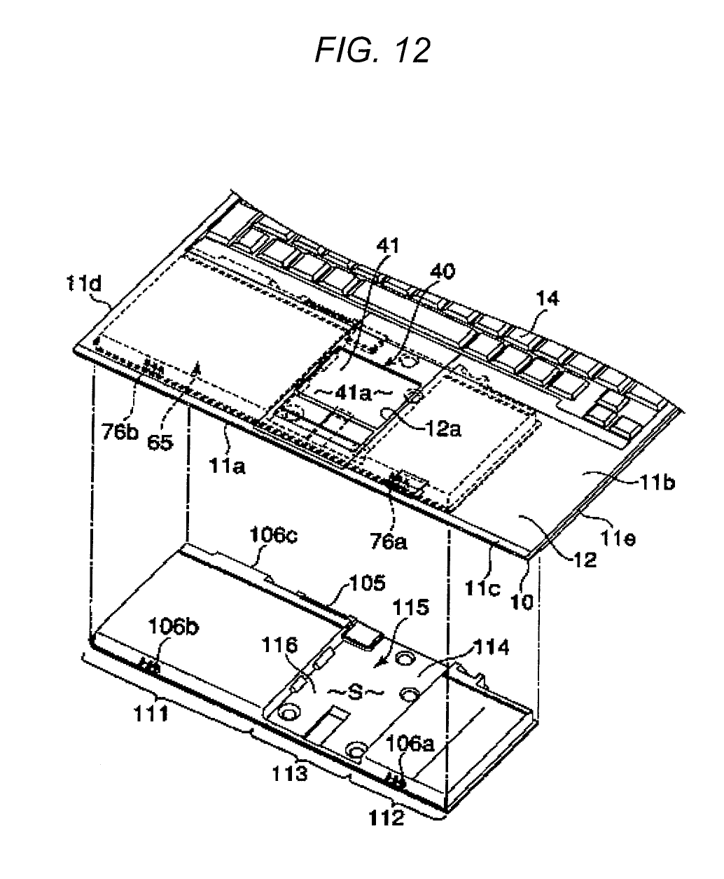

As shown in FIG. 3, an engagement portion 101c is provided on one side surface (rear surface) of a pair of side surfaces of the case 101. Moreover, as shown in FIG. 12, a pair of engagement portions 106a and 106b are provided on the other side surface (front surface) of the pair of side surfaces of the case 101. The engagement portions 106a and 106b are separated in the direction of the length of the case 101.

On the other hand, as shown in FIG. 4, a non-illustrated extension portion extends from the printed wiring board 52, and the power connector 54 is attached to the end of the extension portion. The power connector 54 is electrically connectable to the connector 105 of the battery module 100. The power connector 54 is exposed out of the upright side surface 74 of the first accommodating portion 65.

As shown in FIG. 3, an engagement reception portion 76c engaging with the engagement portion 106c is provided on the upright side surface 74 of the first accommodating portion 65. The engagement reception portion 76c moves in the direction of the width of the first housing 10 in conjunction with a release lever 77 exposed to the outside of the first housing 10. Moreover, as shown in FIGS. 4 and 12, a pair of engagement reception portions 76a and 76b engaging with the engagement portions 106a and 106b are provided on the other upright side surface 75 of the first accommodating portion 65.

The battery module 100 as described above is detachably attachable to the first accommodating portion 65. The battery module 100 serves as the driving power surface for the portable computer 1 in cases such as when the portable computer 1 is used in a place where no commercial power is available, and has a comparatively heavy weight in the portable computer 1.

The battery module 100 is put in the first accommodating portion 65 as shown by the arrow Z in FIG. 3 while being tilted with the rear wall 11f of the first housing 10 facing upward and the connector 105 facing the power connector 54. Then, the battery module 100 is fitted in the first accommodating portion 65 so that the upper surface of the battery module 100 approaches the bottom surface 71 of the first accommodating portion 65. By doing this, the engagement portion 106c engages with the engagement reception portion 76c, and the engagement portions 106a and 106b engage with the engagement reception portions 76a and 76b, whereby the battery module 100 is attached to the first housing 10. At the same time, the connector 105 of the battery module 100 is electrically connected to the power connector 54. Moreover, the battery module 100 is fitted in the first accommodating portion 65 so that the thin part 114 as the recessed portion 115 coincides with the pointing device 40 as an electronic part (the pointing device support portion 68 as a mechanical part).

Moreover, as described above, the outside shape of the battery module (the shape of the case 101) is substantially similar to that of the first accommodating portion 65. Consequently, the lower surface of the case 101 is substantially flush with the outer surface of the bottom wall 11a of the first housing 10. For this reason, of the walls forming the case 101, the wall opposite to the wall facing the pointing device support portion 68 constitutes part of the bottom wall 11a of the first housing 10.

By fitting the battery module 100 in the first accommodating portion 65 of the first housing 10, the pointing device 40 as an electronic part (the pointing device support portion 68 as a mechanical part) is mounted in the first housing 10 so that at least part thereof (substantially the entire part in the present embodiment) coincides with the thin part 114 in the direction of the thickness of the first housing 10 (direction orthogonal to the plane where the portable computer 1 is placed).

To detach the battery module 100 from the first housing 10, the release lever 77 is slid. Since the engagement reception portion 76c is also slid as the release lever 77 is slid, the engagement reception portion 76c is disengaged from the engagement portion 106c of the battery module 100. Since the rear end portion of the battery module 100 is lifted from the first housing 10 by doing this, the battery module 100 is taken out of the first housing 10 (the first accommodating portion 65) by grabbing the rear end portion of the battery module 100 with fingers.

With the above-described structure, the first housing 10 can be made thinner by the thickness of the bottom wall 11a than when the battery module 100 is structured in an area sandwiched between the bottom wall 11a and the upper wall 11b of the first housing 10. Furthermore, the first housing 10 can be made further thinner by the thickness of the pointing device 40 than when the conventional battery module having a flat outside shape is fitted in the first housing 10 while coinciding with the pointing device 40.

Further, the electrical capacity of the battery module 100 can be made substantially the same as that of the conventional battery module 100 having the three in series, two in parallel configuration and a flat outside shape. Further, the outer surface of the battery module 100 is hidden while facing the plane such as a top plate B where the portable computer 1 is placed. Thus, in the above-described normal use condition, the battery module 100 is not exposed to the outside, which enhances appearance.

Moreover, the battery module 100 is formed so that the outer surface (lower surface) of the case 101 of the battery module 100 and the outer surface of the bottom wall 11a of the first housing 10 are substantially flush with each other. For this reason, by providing leg portions 30a to 30f on the outer surface of the case 101 of the battery module 100 and the outer surface of the bottom wall 11a of the first housing 10, the portable computer 1 can be fixed onto a plane such as the top plate B with stability.

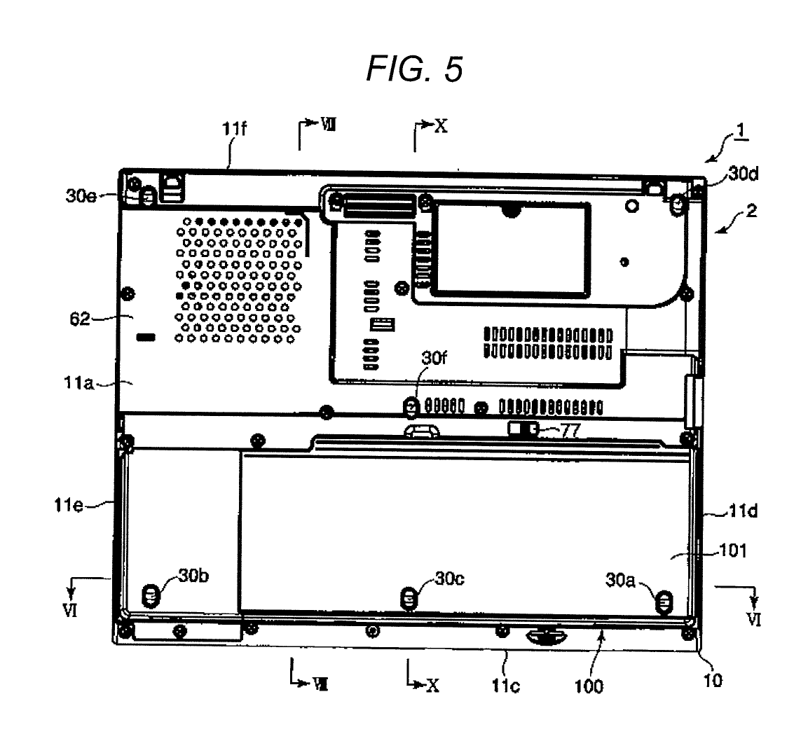

That is, as shown in FIGS. 2 and 5, on the outer surface of the bottom wall 11a of the first housing 10, more than one, for example, three leg portions 30a, 30b and 30c are provided on the front side, and more than one, for example, two leg portions 30d and 30e are provided on the rear side. Moreover, the leg portion 30f is provided substantially in the center of the outer surface of the bottom wall 11a of the first housing 10. The front side leg portions 30a to 30c include a pair of leg portions 30a and 30b disposed so as to be separated in the direction of the width and the leg portion 30c provided at the center between the leg portions 30a and 30b. The rear side leg portions 30d and 30e are separated in the direction of the width. Of the three front side leg portions 30a to 30c, the two leg portions 30a and 30c are provided in the case 101 of the battery module 100.

Consequently, as shown in FIGS. 6, 8 and 10, when the portable computer 1 is placed, for example, on the top plate B of a desk, the leg portions 30a to 30f are in contact with the upper surface of the top plate B. Since the three leg portions 30a to 30c are provided on the front side in this portable computer 1, the portable computer 1 can be fixed on the top plate B with stability also when the pointing device 40 provided in the center of the palm rest 12 is operated.

As described above, the portable computer 1 of the present embodiment is provided with: the first housing 10 having the pointing device 40 as an electronic part and the pointing device support portion 68 as a mechanical part; and the battery module 100 provided in the first housing 10. The battery module 100 is provided with the case 101 and the plurality of battery cells 102a to 102f.

The case 101 has: the first part 111 accommodating one or more battery cells 102a to 102d; the second part 112 accommodating one or more battery cells 102e and 102f; and the third part 113 connecting the first part 111 and the second part 112 together. The third part 113 has the recessed portion 115, and when mounted in the first housing 10, the pointing device 40 and the pointing device support portion 68 are situated in a space S at least part of which is formed by the recessed portion 115.

In other words, the third part 113 has the thin part 114. The thickness d2 of the thin part 114 is smaller than the thickness d4 of the first and second parts 111 and 112 and the thickness d1 of the battery cells 102a to 102f, and the pointing device 40 and the pointing device support portion 68 at least partly coincide with the thin part 114 in the direction of the thickness of the first housing 10 (the direction of the thickness of the battery module 100) when mounted in the first housing 10.

Further, in other words, the third part 113 has the concave portion 116, and the pointing device 40 and the pointing device support portion 68 at least partly coincide with the concave portion 116 (the bottom 116a of the concave portion 116) when mounted in the first housing 10.

Consequently, the thickness of the portable computer 1 can be reduced.

Further, it is typical that a power proportional to the sum of the volumes of the battery cells 102a to 102f is obtained from the battery module 100. In the battery module 100 of the portable computer 1 of the present embodiment, the four battery cells 102a to 102d are arranged in two rows and two columns in the first part 111, the two battery cells 102e and 102f are arranged in one row and two columns in the second part 112, and these are electrically connected. Consequently, a power similar to that of the conventional battery module 100 having the so-called three in series, two in parallel configuration is obtained.

Although it is necessary to provide two connectors 105 and two power connectors 54 when the battery module 100 is divided into two, in the battery module 100 of the portable computer 1 of the present embodiment, the first part 111 accommodating the battery cells 102a to 102d and the second part 112 accommodating the battery cells 102e and 102f are separate from each other with electrical connection being established therebetween. For this reason, the number of connector 105 and the number of power connectors 54 may be one.

Further, since the battery module 100 which is a heavy component is disposed on the hand side in the portable computer 1 of the present embodiment, when the portable computer 1 is pivoted from the closed position to the opened position, the display module 3 can be opened in a stable state.

Furthermore, the printed wiring board 52 is disposed on the rear side where the connector 105 is disposed. For this reason, the rotation pattern can be facilitated. Moreover, since the signal propagation distance can be reduced, the signal inputted to the printed wiring board 52 and the signal outputted from the printed wiring board 52 can be transmitted quickly.

Moreover, the amount of heat generation, during operation, of the CPU (not shown) provided on the printed wiring board 52 tends to increase as the processing speed increases or the number of functions increases. Since the heat generation amount of the battery module 100 is small compared with such a CPU, even though the battery module 100 is disposed under the palm rest 12, the heat generation of the portable computer 1 does not readily affect the operation of the keyboard 14 and the like.

While that an electronic part and a mechanical part at least partly coincide with the thin part 114 in the direction of the thickness when mounted in the first housing 10 may include a case where the electronic part and the mechanical part are in contact with the thin part 114, it may include a case where the electronic part and the mechanical part coincide therewith with a slight gap from the thin part 114. Moreover, as in the present embodiment, the pointing device 40 as the electronic part may coincide with the thin part 114 with another part such as the pointing device support portion 68 in between.

Likewise, while that the electronic part and the mechanical part at least partly coincide with the concave portion 116 when mounted in the first housing 10 may include a case where the electronic part and the mechanical part are in contact with the bottom 116a of the concave portion 116, it may include a case where the electronic part and the mechanical part coincide therewith with a slight gap from the bottom 116a of the concave portion 116. Moreover, as in the present embodiment, the pointing device 40 as the electronic part may coincide with the bottom 116a of the concave portion 116 with another part such as the pointing device support portion 68 in between.

The shape, the number and the position (all, or one or two) of the concave portion 116 as the recessed portion 115 are arbitrary. The concave portion is determined according to the position where the coinciding electronic or mechanical part is disposed.

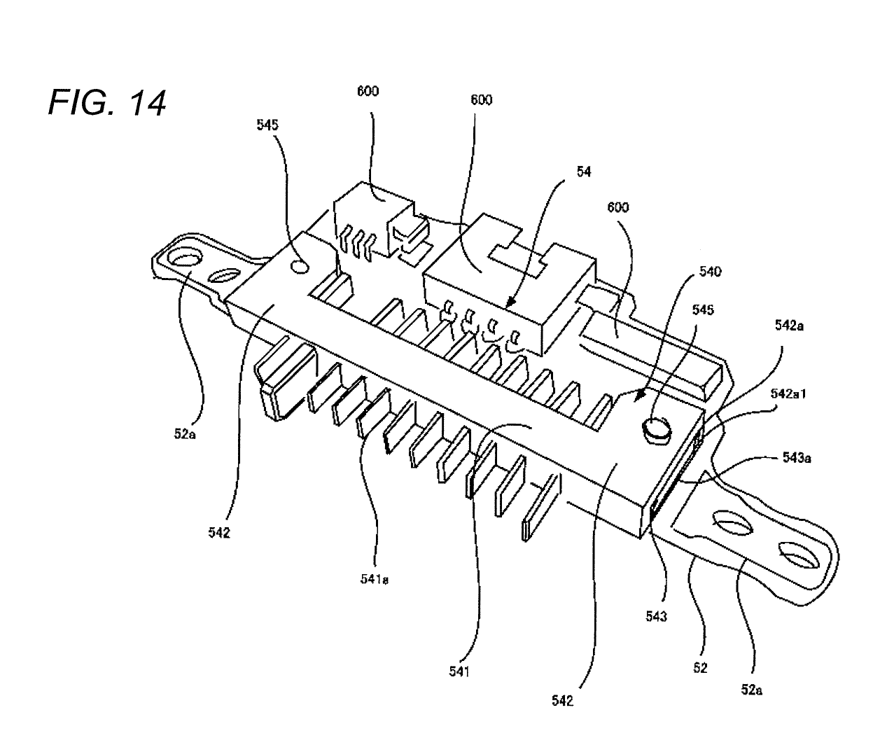

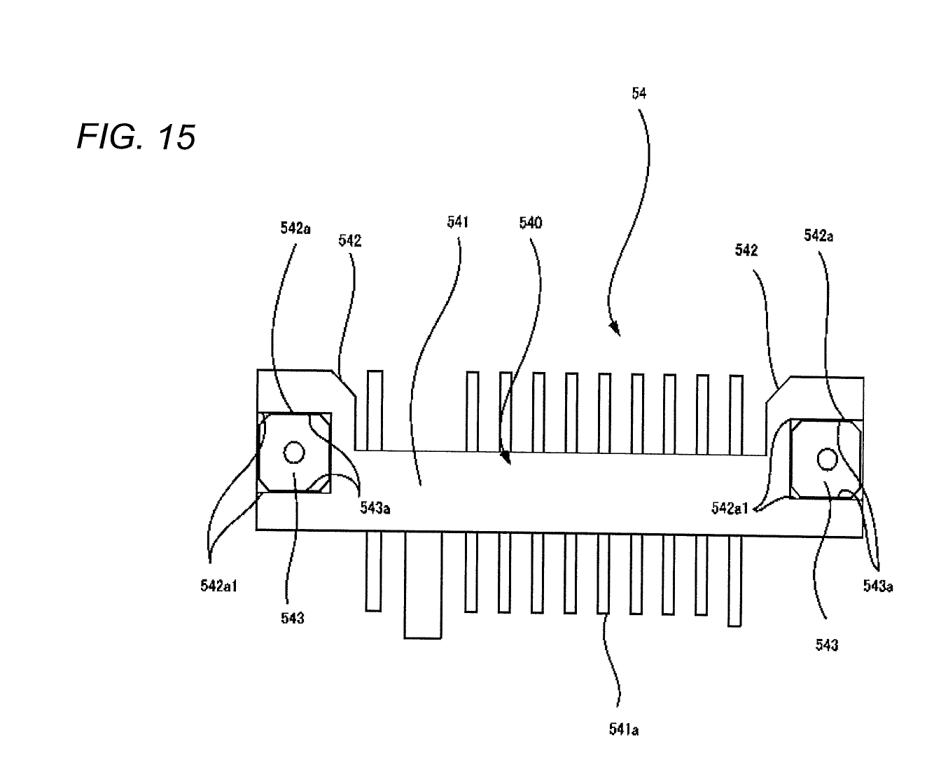

Next, referring to FIGS. 14 and 15, the structure of the battery connector and the structure around the circuit board including the battery connector in the present embodiment will be described. FIG. 14 is a perspective view of the circuit board where the battery connector is mounted in the present embodiment. FIG. 15 is a cross-sectional view of the battery connector in the present embodiment.

As shown in FIGS. 14 to 15, the power connector 54 of the present embodiment has a connector housing 540. The connector housing 540 has: a terminal portion 541 having a terminal 541a connected to the connector 105 of the battery module 100; and side portions 542 continuous with the terminal portion 541 and provided with depressed portions 542a depressed toward the terminal portion 541. The terminal 541a has a structure where metal plate members are arranged. A nut (fitted member) 543 is fitted in each depressed portion 542a. A screw (fixing member) 545 fixing the power connector 54 and the printed wiring board 52 is passed through each nut 543.

In the present embodiment, the depressed portions 542a in which the nuts 543 are fitted are depressed toward the terminal portion 541. By providing such a structure, the nuts 543 can be inserted from the side surfaces of the side portions 542. For example, in the vicinity of the terminal portion 541, in particular, in the part where the terminal portion 541 and the printed wiring board 52 are connected in the direction of extension of the terminal 541a, a plurality of other parts 600 and the like are disposed in order to efficiently establish electrical connection with the power connector 54. However, in areas in the vicinity of the side portions 542 outside the part where the terminal portion 541 and the printed wiring board 52 are connected in the direction of extension of the terminal 541a, other parts which are large in height when mounted are not very likely to be disposed since the areas are situated on the outer edges of the printed wiring board 52. Therefore, by providing a structure where the nuts 543 can be inserted from the side surfaces of the side portions 542, the efficiency of the insertion of the nuts 543 can be increased. Moreover, the printed wiring board 52 has areas 52a extending in the direction of fitting of the nuts 543 from the ends of the side portions 542. Thereby, the nuts 543 can be inserted along the surface of the printed wiring board 52.

As shown in FIG. 15, in the present embodiment, when the cross section of the connector 54 is viewed from the direction of insertion of the screws 545, the nuts 543 are fixed by the support in three directions. That is, no walls for holding the nuts 543 are necessary on the side surfaces of the side portions 542, so that the connector length can be designed to be small (in a direction orthogonal to the direction of extension of the terminal 541a). The surface of part of each nut 543 is exposed from the depressed portion 542a to constitute part of the side surface of the side portion 542.

As shown in FIG. 15, the depressed portions 542a each extend in the direction of extension of the terminal 541a, that is, in a direction orthogonal to the direction of insertion of the battery module 100, and have an inner wall portion 542a1 facing a peripheral wall 543a of the nut 543. For the connector housing 540 of the present embodiment, dimension design is made so that the peripheral wall 543a of the nut 543 and the inner wall portion 542a1 abut on each other. Although not shown, in the present embodiment, dimension design is made so that the upper and lower surfaces of each nut 543 also abut on the inner wall portion 542a1. That is, the depressed portions 542a of the connector housing 540 each extend in a direction orthogonal to the direction of extension of the terminal 541a, and have the inner wall portion 542a1 in four positions facing and abutting on the nut 543. With this structure, the nuts 543 can be tightly held in the depressed portions 542a.

As shown in FIG. 15, the nuts 543 of the present embodiment have a shape such that the cross section when viewed from the direction of insertion of the screws 545 is quadrilateral. The shape of the cross sections of the nuts 543 approaches a circle as the number of angles of the cross sections increases. For example, if the cross sections of the nuts 543 have a multi-angle shape, when the screws 545 are inserted, the nuts 543 rotate together with the screws 545 in the depressed portions 542a. However, since the cross sections of the nuts 543 of the present embodiment when viewed from the direction of insertion of the screws 545 are quadrilateral, the possibility of occurrence of the above-mentioned problem is low.

As described above, according to the structure of the present embodiment, a connector realizing a size reduction is provided, so that a high mounting density is enabled. In addition, assembling workability is improved.

Moreover, the electronic apparatus is not limited to the above-described embodiment as it is, but may be embodied while components thereof are modified without departing from the gist of the present invention in implementation. Further, various inventions may be formed by appropriately combining a plurality of components disclosed in the above-described embodiment. For example, some components may be deleted from all the components shown in the embodiment. Further, components according to different embodiments may be combined as appropriate.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing formed with an opening;
a battery module comprising a connection portion and at least partly accommodated in the opening;
a circuit board accommodated in the housing;
a connector portion comprising:
a terminal portion comprising a terminal connected to the connection portion of the battery portion; and
a side portion connected to the terminal portion and comprising a depressed portion depressed toward the terminal portion; and
a fitted member fitted in the depressed portion and configured to fix the connector portion and the circuit board.

2. The electronic apparatus according to claim 1, wherein:
the depressed portion comprises a wall portion orthogonal to an extending direction of the terminal; and
the fitted member comprises a peripheral wall portion facing along the wall portion.

3. The electronic apparatus according to claim 2, wherein
the fitted member is a nut having a quadrilateral shape.

4. The electronic apparatus according to claim 3, wherein
the fixing member is passed through a hole laterally-located in relation to a side of the terminal portion.

5. The electronic apparatus according to claim 3, wherein
a part of the peripheral wall portion of the fitted member is exposed out of the depressed portion to be part of the side surface.

6. The electronic apparatus according to claim 3, wherein
the circuit board comprises an area extending in a direction of fitting of the fitted member into the depressed portion.

7. The electronic apparatus according to claim 3, wherein:
the depressed portion comprises four wall portions orthogonal to the direction of extension of the terminal; and
the fitted member abuts on each of the four wall portions.

8. An electronic apparatus comprising:
a housing;
a circuit board accommodated in the housing;
a connector portion having: a terminal portion having a terminal connected to another part; and a side portion having a depressed portion depressed toward the terminal portion and that is continuous with the terminal portion; and
a fitted member fitted in the depressed portion and configured to fix the connector portion and the circuit board.

9. The electronic apparatus according to claim 8, wherein:
the depressed portion comprises a wall portion orthogonal to a direction of extension of the terminal; and
the fitted member comprises a peripheral wall portion facing along the wall portion.

10. The electronic apparatus according to claim 8, wherein
the fitted member is a nut having a quadrilateral shape.
